(19) United States
(12) Patent Application Publication
(10) Pub. No.: US 2008/0205002 A1
(43) Pub. Date: Aug. 28, 2008

(54) Composite board for heat dissipation and forming methodology

(76) Inventor: Tat Wai Calvin Chui, Causeway Bay (HK)

Correspondence Address: BACHMAN & LAPOINTE, P.C., 900 CHAPEL STREET, SUITE 1201, NEW HAVEN, CT, 06510, US

(21) Appl. No.: 11/879,277

(22) Filed: Jul. 17, 2007

(30) Foreign Application Priority Data
Feb. 22, 2007 (CN) 200710085813.5

(51) Int. Cl. H05K 7/20

(52) U.S. Cl. 361/699

(57) ABSTRACT

A composite board for heat dissipation, comprises two or three or more flat boards connected together through welding/bonding. There are multiple pipes formed between the flat boards for the heat dissipation liquid passing through. The heat dissipation liquid is controlled by a water pump. The electronic elements that generate heat contact the composite board directly or indirectly. A circuit is formed on at least one of the surfaces of the composite board, and the electronic elements are welded to the circuit. Thus, the heat in the case and the circuit board used in a computer, especially a notebook computer, may be dissipated more efficiently, available spaces may be increased, and the heat dissipation of airflow may be facilitated.

### FIELD OF THE INVENTION

This invention relates to a composite board for the heat dissipation of computers or electrical devices, and more particularly to a composite board of which cases, containers or circuit boards may be formed.

### BACKGROUND OF THE INVENTION

As the advancement of technology, the requirement for heat dissipation has been increasing, since more and more heat is generated in computers or electrical devices. The presently available central processing units (CPUs) and graphic processing units (GPUs) of computers generate more heat than before, for example, Opteron CPU has TDP (thermal design power) of 89 W, Prescott and Xeon CPUs has TDP greater than 103 W; NV40 and R420 GPUs has TDP of greater than 100 W; an integrated computer with dual CPUs and a NV40 GPU has TDP of greater than 300-350 W. Additionally, the design of Opteron facilitates the integration of 4-CPUs or 8-CPUs within single computer body. Water cooling method for heat dissipation, a method for heat dissipation commonly are used in the prior art, to take care the every heat generated by the multiple heat source than using water tubes placed in the case for heat dissipation. In fact, it occupied the space constricted area by massive bent to sharp turn water pipes and water hoses. However, in current DIY market, it is difficult for a user to deal with motherboard components replacement if hard disks and power supply is also cooled using conventional water cooling method, since water pipes are connected and thus water must be discharged in the replacement of elements, especially for power supply which contains elements with high voltage. Of course, if the power supply is originally designed and maintenance carried out by the maintenance person, the users cannot upgrade by themselves, the problem mentioned would not occur. But it still added the difficulty to the system maintenance. Besides, if the system is originally designed with air-cooled for heat dissipation, the heat of the elements on the motherboard would be carried away with the help by the fan of the CPU. If a user replaces it with the water block by itself, the fan would be removed, and this shall be problematic for the MOSFET in voltage regulation module (VRM) of peripheral parts.

In China patent No. CN2598043Y, a computer case is disclosed, in which the temperature is lowered through carrying away the heat in the case by the dissipating liquid flowing in the case. However, the cooling effect is not satisfactory, since the multiple heat sources locally generated are difficult to be dealt with, especially if heat generated in space constrict area and motherboard components replacement would be a complicated task.

In China patent No. CN2489375Y, a computer case is also disclosed, at a side of which there is a container for cooling liquid, there is a heat dissipater beside the CPU, and there is a loop between the container for cooling liquid and the pump dissipater serially connected by pipes, which exists the same problems as above.

### SUMMARY OF THE INVENTION

The objective of this invention is to provide a composite board for more efficient heat dissipation, especially, for example, a case and a circuit board used in a notebook computer, which may increase available spaces and help the heat dissipation of the electronic elements.

The present invention provides a composite board for heat dissipation, comprising two or three or more layers of flat boards connected together through welding/bonding, wherein there are multiple pipes/channels formed between the flat boards for the heat dissipation liquid passing through, the heat dissipation liquid is controlled by a water pump, electronic elements that generate heat contact the composite board directly or indirectly

The composite board forms a fireproof and waterproof computer case or container by well combination of the selected material to form the case accordingly.

Printed circuit board of the electronic elements are fixed on the composite board of the case and the electronic elements are welded to the printed circuit board.

A hard disk drive, a CD-ROM drive and a power supply are closely mounted on the composite board.

The electronic elements are connected to the composite board through heat conducting pipes.

A metal plate connects elements to flatten the different heights, and thus the metal plate contacts the composite board.

The heat dissipation liquid is a mixture of water and alcohol, or hydrocarbon oil.

A print circuit is formed on at least one of the surfaces of the composite board, and the electronic elements are welded to the circuit.

The composite board comprises ground/grind or pre-molded mirror plane symmetrical flat boards.

The material of the flat boards is selected from glass, metal, heat-resistant plastic, and some material was ideal for natural material that can be make hard such as clay, ceramic or soft stone, as marble, or waterproof wood (wood with waterproof treatment).

The present invention provides also a method for forming the composite board for heat dissipation, comprising reserving spaces between oppositely placed surfaces of two flat boards to be connected using grinding or pre-molding method, then welding or bonding (not only limited to welding as such as sticking, hot press due to different material should use different process) the surfaces with reserved spaces together, to form multiple slots within the flat boards for the heat conducting liquid passing through.

### BRIEF DESCRIPTION OF THE DRAWINGS

FIGS. 1-1a shows the composite board used for the case and supporting plate according to the present invention, wherein FIG. 1a shows the two flat boards prior to composing.

FIGS. 2-2a shows the composite board used for the case and supporting plate according to the present invention, wherein FIG. 2a shows the three flat boards prior to composing.

FIGS. 3-3c shows a composite board with electronic elements.

FIG. 4 shows the composite board in contact with a CPU.

FIG. 5 is a schematic view of elements with different heights prior to being in contact with the composite boards.

FIG. 6 is a sectional view of elements with different heights on the base plate in contact with the composite boards.

FIG. 7 is a schematic view of hard disk drive in connection with the composite boards.

FIG. 8 is a schematic view of the heat dissipation connection of the power supply

FIG. 9 shows the dissipater externally connected to the case.

FIGS. 10 and 10a shows another form of the external connection of the dissipater to the case.

FIGS. 11-11c shows an alternative embodiment of composite board.

### DETAILED DESCRIPTION OF THE INVENTION

The present invention shall be described with more details in conjunction with the drawings.

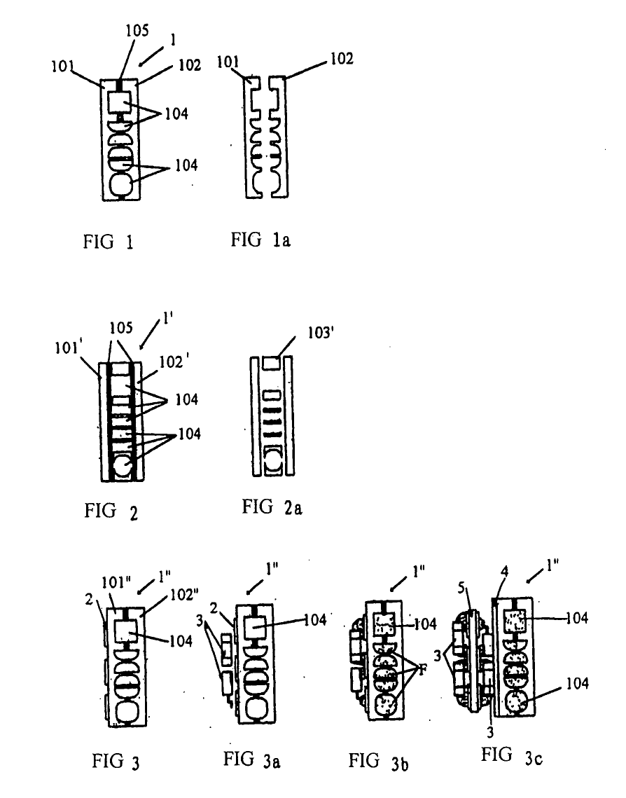

FIGS. 1 and 1a show a composite board 1 in the form of two flat boards 101 and 102, in one of the surfaces of which there are reserved spaces through grinding or pre-molding, then the two flat boards with reserved spaces are welded together with hermetic layer 105 to form multiple slots or channels 104 within the flat boards for the heat conducting liquid passing through. The material of the flat boards is selected from P.C. (polycarbonate), glass, metal, heat-resistant plastic and some material was ideal for natural material that can be make hard such as clay, ceramic or soft stone as marble, or wood (waterproofed). Since the board is composed, it is called composite board. Channels 104 in corresponding shapes may be formed when the two flat boards are welded together, since there are corresponding slots in the opposite surfaces of the two flat boards, and heat dissipation liquid may circulate through such channels. The heat dissipation liquid may be hydrocarbon oil (such as Alpha oil of Opticool), a mixture of water and alcohol, or other suitable liquids.

The composite board may have multiple parallel channels, and the ends of each channel may be connected to each other through joints another composite board. Preferably, there is a sinuous channel (not shown) formed in each composite board, and thus each board has only one inlet channel end and one outlet channel end (see FIG. 5). The ends of every channels may be assembled together, and thus they may have a common inlet channel end and a common outlet channel end (not shown), but, with reference to FIG. 5, the heat conducting liquid F may be converged at the common inlet channel end and the common outlet channel end.

As shown in FIGS. 2-2a, the composite board in the form of three flat boards comprises two flat boards 101′ and 102′, with another board 103′ interposed between, such as multiple spaced material formed through grinding, preferable nonmetal material. After being composed, the spaces between multiple spaced materials 103′ form channels 104′.

Preferably, flat boards are metal when used as heat dissipation plates, and nonmetal when used as substrates of circuit boards.

FIGS. 3-3c show that on the surface of one side of the composite board 1′, a conducting line or copper sheet 2 is formed through, for example, etching, so flat boards 101″ and 102″ are nonmetal. Then, the electronic elements are welded on the surfaces of flat boards 101″ and 102″. Microchannels are formed through, for example, grinding or pre-molding, on the other side of the flat board 101″, then the side is covered by the other flat board 102″, thus forming multiple microchannels 104 for the heat dissipating liquid passing through. The microchannels are preferably in communication with each other and have one inlet and one outlet. In this manner, a circuit board with heat dissipation channels is formed.

FIG. 3c shows that a heat conducting rubber 4 is formed on one side of the flat board 101″, thus the electronic elements 3 generating heat on double-sided printed circuit board 5 may be in direct contact with the heat conducting rubber 4, and the heat of the double-sided circuit board 5 may be conducted through the heat conducting rubber 4 to the fluid within the microchannels 14 and therefore, the flat board 101″ is preferably metal or heat conductive. In another embodiment, a circuit 22 made in a conventional manner may be fixed to a composite board.

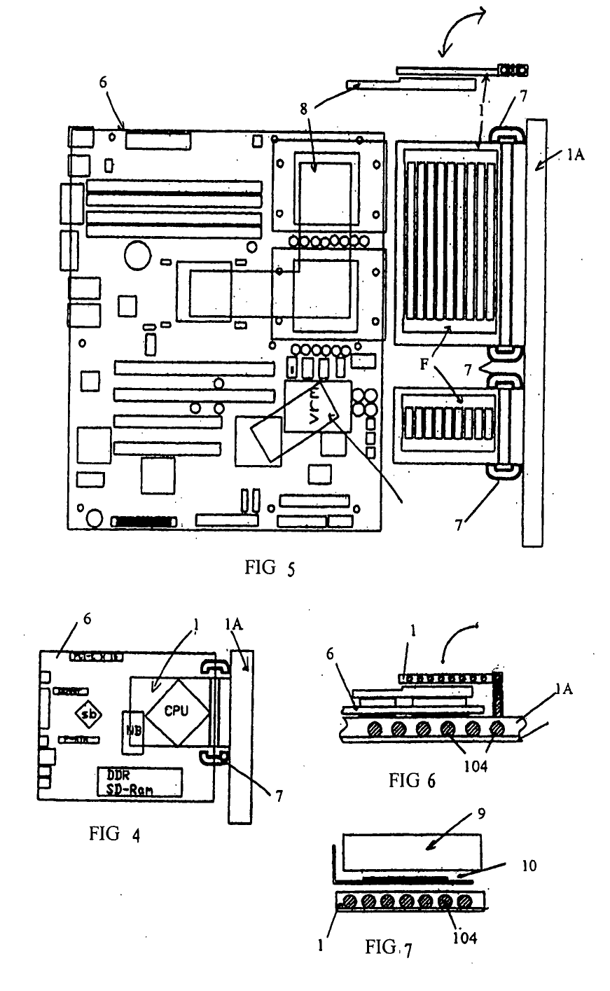

FIGS. 4, 5 and 6 is a heat dissipation method, showing the elements on the host board 6 of the computer that cannot contact directly the composite board, such as the CPU and south and north bridge chips, etc. FIG. 3 shows the host board 6 of a single CPU, FIG. 4 shows the host board of a double CPU and FIG. 5 is cross sectional view of a CPU in contact with the composite board. It may be seen from the figures that the two composite boards 1 and 1A are connected substantially perpendicularly by two joints 7, with the channels 104 of them in communication one another and one board may rotate around the other. Thus, when an element is replaced, only the composite board 1 is needed to be rotate upwardly to expose the host board 6 without hindering the replacement of the element. The composite board 1A is connected to the case as the supporting board, and the other composite board 1 is in contact directly or indirectly with heat-generating elements. Where the elements on the host board 6 are different in height, a metal plate 8 may connect them and then, the metal plate 8 contacts the composite board. The host board 6 is connected to the case through heat conducting materials.

In this manner, there would be no need of two or three fans for a conventional power supply with a large power to help the heat dissipation, and meanwhile, the noise thus generated would be reduced.

Additionally, it is obvious to the skilled in the art to use externally mounted dissipaters for multiple CPUs or computers (not shown) and have channels connected in serial or in parallel to composite boards for heat dissipation with single externally-mounted dissipater. A water pump (preferably a screw pump) is used enabling the communication and circulation of the heat dissipation liquid within the composite board. The side of the dissipater contacting the case is provided with a copper pipe in communication with the compressor, refrigerant running through inside to facilitate the heat exchange with the case. The fan functions to enhance the convection of the air. The substrate, the hard disk drives, the CD-ROM drives and the power supply may be all mounted closely on the composite board, this enable the whole computing hierarchy carry out thermal management autonomously.

FIG. 7 shows that a hard disk drive 9 is mounted on the composite board 1 with multiple channels 104. Preferably, the hard disk drive 9 is connected to the composite board 1 through heat conducting material 10 comprising metal plates and heat conducting rubber.

FIG. 8 shows a particular design of a power supply 14. Since the power supply generates much heat and it is desirable that there is no liquid flowing in the power supply 14, a heat pipe 13 is used to transfer the heat of the transformer 15 to the composite board 1B of the case of the power supply to carry the heat away. In addition, only a low-speed fan (not shown) may be left in the power supply to serve for air convection. In this way, there would be no need of two or three fans for a conventional power supply with a large power to help the heat dissipation, and meanwhile, the noise thus generated would be reduced.

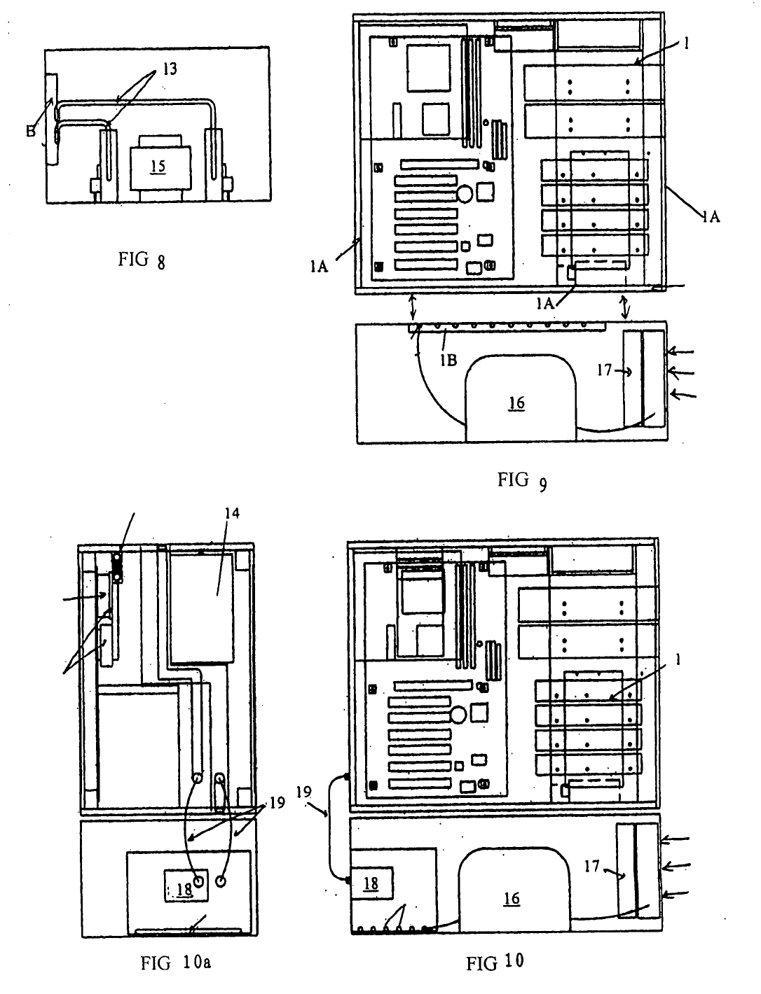

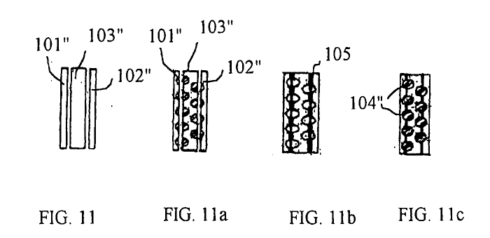

FIGS. 9 and 10 are schematic views of heat dissipation of composite board case with external refrigeration cooling system. Since presently available central processing units and graphic processing units of computers generate more heat than before, for example, Opteron CPU has TDP (thermal design power) of 89 W, Prescott and Xeon CPUs has TDP greater than 103 W; NV40 and R420 GPUs has TDP greater than 100 W; an integrated computer with dual CPUs (see FIG. 4) and a NV40 GPU has TDP of greater than 300-350 W. Additionally, the design of Opteron facilitates the integration of 4-CPUs or 8-CPUs in a single computer body. In such cases, external refrigeration cooling system shall be used in heat dissipation, since it is very difficult to carry the potential heat of the liquid away using air at ambient temperature. In FIGS. 9, 10 and 10a, the integrated computer only needs to be stacked and contacted with the external dissipater. The external dissipater comprises a compressor 16 sequentially connected by a copper pipe, and heat dissipation portion 20 with a fan 17, and another composite board 1B in contact with the substrate (preferably comprising a composite board with multiple channels) of the integrated computer.

FIGS. 10 and 10a are different from FIG. 9, in that a channel 19 is connected to enable the integrated computer to be in fluid communication with the external dissipater. This is advantageous since, if several computers are used, they may be connected in serial or in parallel by a water tubes 19 and the heat may be dissipated using a single external dissipater. The water pump 18 and the case are in fluid communication with the heat dissipation liquid within the composite board of the supporting plate and enable the liquid to circulate. The side of the dissipater contacting the case is provided with a copper pipe in communication with the compressor 16, facilitating the heat exchange with the case. The fan 17 functions to enhance the convection of the air. It can also be seen from the figures that the substrate, the hard disk drive, the CD-ROM drive and the power supply may be all mounted closely on the composite board.

The present invention is not limited to the embodiment mentioned above, Various modifications may be made to the present invention by those skilled in the art according to above descriptions of the invention, without departing from the scope of the present invention, and which are also intended to be protected. For example, each composite board might have more than one layer of channels. As shown in FIGS. 11-11c, a composite board is in the form of three flat boards comprises two boards 101″ and 102″, with another board 103″ interposed between, such that both side of another board 103″ are reserved spaces through grinding or pre-molding, while only one side of the boards 101″ and 102″ adjacent to another board 103″ are reserved spaces through grinding or pre-molding, Then the three boards are welded together with hermetic layer 105 to form multiple slots or channels 104″. That is, multiple slots or channels in the composite board form at least one or two sinuous channel(s), and thus each sinuous channel has one inlet channel end and one outlet channel end for each/same liquid. In other words, one of said sinuous channels can be used for one liquid, another of said sinuous channels can be used for another liquid with different properties such as higher/lower temperature, thermal conductivity, etc. Therefore, different liquids can be used to more precisely cool different heat sources on the different zones/sides of the composite board.

What is claimed:

1. A composite board for heat dissipation, comprising at least two flat boards connected together through welding/bonding, multiple pipes formed between the flat boards for a heat dissipation liquid passing therethrough, the heat dissipation liquid being controlled by a water pump, and electronic elements that generate heat contacting the composite board directly or indirectly.

2. A composite board according to claim 1, wherein the composite board forms a fireproof and waterproof computer case or container or supporting plate.

3. A composite board according to claim 1, wherein printed circuits of the electronic elements are formed on the composite board and the electronic elements are welded to the printed circuits.

4. A composite board according to claim 1, wherein at least one of a hard disk drive, a CD-ROM drive and a power supply are closely mounted on the composite board.

5. A composite board according to claim 1, wherein the electronic elements are connected to the composite board through heat conducting pipes.

6. A composite board according to claim 1, wherein a metal plate connects the electronic elements with different heights contactually, and the metal plate contacts the composite board.

7. A composite board according to claim 1, wherein the heat dissipation liquid is a mixture of water and alcohol, or hydrocarbon oil.

8. A composite board according to claim 1, wherein a circuit is formed on at least one surface of the composite board, and the electronic elements are welded to the circuit.

9. A composite board according to claim 1, wherein the composite board comprises ground/grind or pre-molded mirror plane symmetrical flat boards.

10. A composite board according to claim 1, wherein the flat boards are made of a material selected from the group consisting of glass, metal, heat-resistant plastic, clay, ceramic or soft stone, marble, and waterproof wood.

11. A composite board according to claim 1, wherein multiple pipes form at least one sinuous channel in the composite board, and each said at least one sinuous channel has one inlet channel end and one outlet channel end.

12. A composite board according to claim 1, wherein the composite board is stacked on a top of an external heat dissipator, and the heat is transferred by contact between the dissipater and the composite board.

13. A method for forming a composite board for heat dissipation, comprising reserving spaces between oppositely placed surfaces of two flat boards to be connected using a grinding or pre-molding method, then welding/bonding the surfaces with reserved spaces together, to form multiple channels within the flat boards for a heat conducting liquid passing through.

14. A method for forming a composite board for heat dissipation, comprising sandwiching multiple spaced materials between two flat boards, then welding/bonding the flat boards and the spaced materials together so that spaces between the spaced materials form channels for a heat conducting liquid passing through.
